(19) United States
(12) Patent Application Publication
(10) Pub. No.: US 2015/0082617 A1
(43) Pub. Date: Mar. 26, 2015

(54) PROCESS FOR CHARGING A LEAD BATTERY TAKING INTO ACCOUNT ITS OXIDATION, PROCESS FOR GENERATING A NOMOGRAM FOR THE CHARGING PROCESS, DEVICE ASSOCIATED WITH THE CHARGING PROCESS, RECORDING MEDIUM AND COMPUTER PROGRAM WHICH ARE ASSOCIATED WITH THE CHARGING PROCESS

(71) Applicant: COMMISSARIAT A L'ENERGIE ATOMIQUE ET AUX ENERGIES ALTERNATIVES, Paris (FR)

(72) Inventors: Rémy Christin, Cruseilles (FR); Sylvie Genies, Saint Egreve (FR); Jean-Marie Klein, Viviers Du Lac (FR)

(73) Assignee: COMMISSARIAT A L'ENERGIE ATOMIQUE AUX ENERGIES ALTERNATIVES, Paris (FR)

(21) Appl. No.: 14/390,723

(22) PCT Filed: Apr. 2, 2013
(86) PCT No.: PCT/EP2013/056873

§ 371 Date: Oct. 3, 2014

(30) Foreign Application Priority Data
Apr. 4, 2012 (FR) 12 53064

(51) Int. Cl. G01R 31/36; H01M 2/36; H02J 7/00

(52) U.S. Cl. CPC G01R 31/3606; H02J 7/0052; H01M 2/36
USPC 29/593; 320/137; 320/150; 29/623.5

(57) ABSTRACT

The process for charging a lead battery comprises an initialisation phase (E1), during which a value representative of an amount of lead oxide of the negative active material of the battery is determined, and a charging phase (E2), the duration of which is determined as a function of the value representative of amount of lead oxide.

### TECHNICAL FIELD OF THE INVENTION

The invention relates to the field of lead batteries.

A subject-matter of the invention is more particularly a process which makes it possible to recharge a lead battery, in particular after a period of storage without electrolyte which has brought about oxidation of the lead present in the battery.

### STATE OF THE ART

Currently, manufacturers of batteries and their providers limit the storage time of dry charged batteries (while also indicating ranges of temperatures, indeed even of moisture content, to be observed) in order to guarantee a full and complete capacity for a standardised initial charging time. The term “dry charged” is understood to mean, in the present description, a battery which has been filled by its electrolyte and then charged before being subjected to draining, so as to remove all its electrolyte before storage.

More generally, in order to overcome the case where, despite observing the storage instructions, the battery exhibits abnormal oxidation of its active material, the recommended initial charging procedure, after addition of the electrolyte, is very greatly overscaled in charging time (48 h with a minimum load of 5 A for 100 Ah of nominal capacity). In addition, in the event of strong oxidation of the negative active material, the procedures for filling with electrolyte (themselves also standardised) result in additional periods of time before putting into service, indeed even the consideration of these batteries as failing. This is because, in these procedures, the temperature of the electrolyte must not exceed 30° C., which requires filling by successive additions of electrolyte, interrupted by major pauses in order for it to cool down.

Consequently, the phases for charging a lead battery which has been oxidized can be lengthy. This thus results in a problem of optimisation of the charging time after storage, in particular dry charged, of the battery.

### SUBJECT-MATTER OF THE INVENTION

The aim of the present invention is to provide a solution which makes it possible to optimise the battery during its first charging, in particular for a dry charged stored battery.

This aim can in particular be achieved by the appended claims and more particularly by a process for charging a lead battery, comprising an initialisation phase, during which a value representative of an amount of lead oxide of the negative active material of the battery is determined, and a charging phase, the duration of which is determined as a function of the value representative of amount of lead oxide.

The invention also relates to a process for the generation of a nomogram intended to be used in the charging process, the said process for the generation of the nomogram comprising the generation of the nomogram from at least one measurement of a physical parameter of an at least partially oxidized lead battery and the correlation of this measurement with a value representative of an amount of lead oxide of the negative active material of the battery.

The invention also relates to a device comprising a battery and a calculation unit configured in order to carry out the charging process; in particular, this device can comprise a temperature sensor, in particular of thermocouple type, configured in order to measure the rise in the temperature during the initialisation phase.

The invention also relates to a data recording medium readable by a computer, on which is recorded a computer program comprising computer program code means for implementing the phases and/or stages of the charging process.

The invention also relates to a computer program comprising a computer program code means suitable for carrying out the phases and/or stages of the charging process, when the program is executed by a computer.

### SUMMARY DESCRIPTION OF THE DRAWINGS

Other advantages and characteristics will emerge more clearly from the description which will follow of specific embodiments of the invention given as nonlimiting examples and represented in the appended drawings, in which:

FIG. 1 illustrates a process for charging a battery,

FIG. 2 represents a graph giving, as a function of the time, the change in the voltage at the terminals of a battery in the charging phase, and the change in the derivative of the voltage,

FIG. 3 represents a process for the generation of a nomogram intended to be used to determine the charging time of a lead battery,

FIG. 4 illustrates a representation of the rate of lead oxide present in a battery before impregnation by its electrolyte as a function of the rise in the temperature in ° C. during an impregnation phase,

FIG. 5 illustrates a representation of the rate of lead oxide present in a battery before impregnation by its electrolyte as a function of the density of its electrolyte recorded after impregnating for 24 hours and returning to ambient temperature, 25° C. in the example, following the exothermicity of the impregnation reaction,

FIG. 6 illustrates a device intended to be used with the charging process.

### DESCRIPTION OF PREFERRED FORMS OF THE INVENTION

The solution described below differs from the prior art in particular in that the aim is not to carry out overscaled charging in order to avoid the problems related to the oxidation of the battery/accumulator but instead to scale the charging as a function of the oxidation of the battery.

In fact, the negative active material of a lead battery normally manufactured is virtually exclusively formed of lead. Before the negative material is brought into contact with its electrolyte in order for the battery to be functional, that is to say during storage, for example dry charged, of the battery, the lead is in direct contact with the air. This contact with the air and the ambient moisture naturally results in this lead becoming oxidized to form lead oxide PbO, which phenomenon gradually accumulates in the course of time.

Consequently, the longer the storage period, the more the lead oxide will accumulate, up to a certain limit which depends on the porosity of the material (surface oxidation).

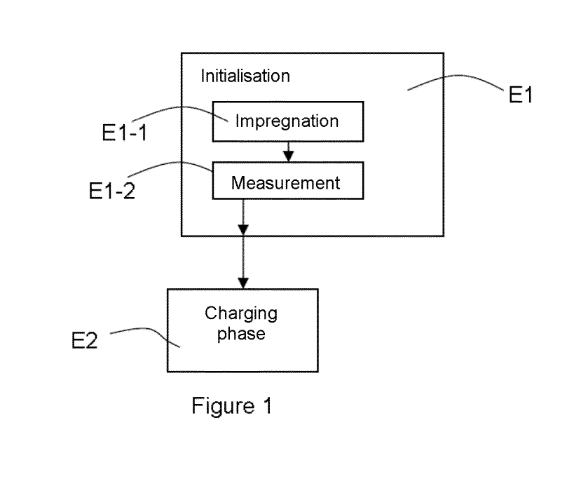

Thus, in order to improve the time for putting into service a lead battery, a process for charging a lead battery/accumulator has been developed (FIG. 1) which comprises an initialisation phase (E1), during which a value representative of an amount of lead oxide in the battery is determined. The process additionally comprises a charging phase (E2), the duration t_{ch} of which is determined as a function of the value representative of amount of lead oxide.

In fact, in the present description, the value representative of the amount of lead oxide in the battery is advantageously the value representative of the amount of lead oxide of the negative active material of the battery, existing in particular at the surface of the said negative active material. The negative active material forms an electrode of the battery. It is understood from what was said above that this lead oxide is formed at the surface of the negative active material of a dry charged lead battery during its storage.

More particularly, the lead oxide formed at the surface of the negative active material of a dry charged lead battery during its storage is distinct from the lead oxide PbO₂ constituting the positive active material of this battery. In fact, PbO₂ is the most oxidized form of lead and is thus chemically inert with respect to the oxidation by the air during the storage (which is not the case with lead Pb, which is oxidized to give PbO during storage). PbO₂ is also chemically inert with respect to sulphuric acid; it thus does not bring about any chemical reaction with the latter which may generate a rise in temperature (PbO₂ is electrochemically active only during use in charging/discharging the battery, the sulphuric acid then playing a role in the associated processes).

In fact, before carrying out the charging process, the battery being stored dry charged, the amount of lead oxide which it is desired to determine is that present immediately before impregnation of the battery by its electrolyte is carried out. Consequently, the initialisation phase can begin by providing an electrolyte-free battery, in particular a dry charged battery, and by then carrying out the impregnation of the latter by its electrolyte.

The behavioural study of the chemical reactions during the addition of the electrolyte (impregnation) and during a phase of charging the battery has shown that it is the site of two consecutive chemical reactions.

The first reaction is defined by the following equation:

PbO+H₂SO₄→PbSO₄+H₂O (1)

Equation (1) begins from the addition of the electrolyte H₂SO₄ to the battery. This addition corresponds to an impregnation of the battery by the electrolyte so that the sulphuric acid of the electrolyte will react completely with the lead oxide PbO to form lead sulphate PbSO₄.

The second reaction takes place during the charging, in particular carried out with a constant current, and is defined by the following equation:

PbSO₄+2H⁺+2e→Pb+H₂SO₄ (2)

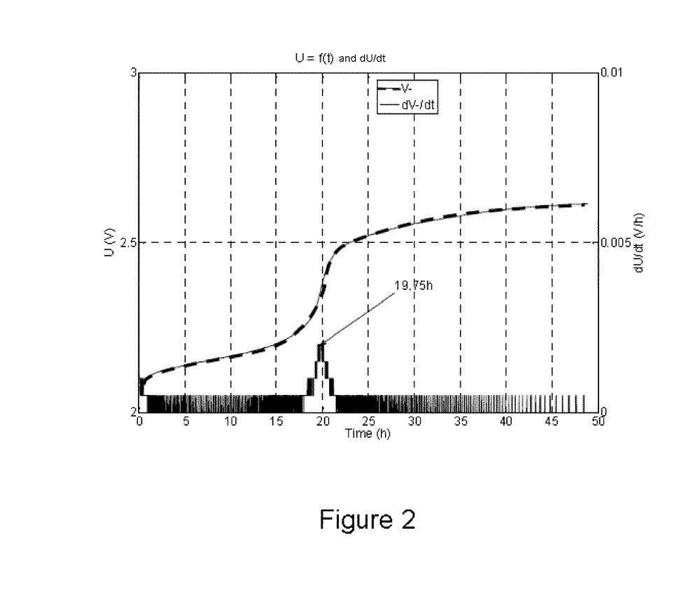

When all the lead sulphate PbSO₄ has been converted into lead, the battery is in a charged state. The amount of PbSO₄ converted into lead can be determined, from the duration of the reaction associated with equation (2), using Faraday's law in the context of constant current coulometry. This law is an analytical method commonly used in electrochemistry and thus known to a person skilled in the art. The analysis of the charging curve U=f(t) obtained, as illustrated in FIG. 2, makes it possible to determine the duration of the reaction of equation (2). FIG. 2 illustrates two curves respectively representative of the change over time in the voltage U (in volts) during the phase of constant current charging and of the change over time in the derivative dU/dt of the curve of the change in the voltage. The duration of the reaction corresponding in the present case to the associated peak at 19.75 h.

Subsequently, the weight of the lead oxide initially present before impregnation can be determined conventionally by the stoichiometry of equation (1).

It thus results from the analysis of these two reactions that, on knowing a value representative of the amount of lead oxide, it is possible to know when the battery will be charged as best as can be done.

Consequently, the initialisation phase E1 can comprise, as illustrated in FIG. 1, a stage of impregnation (E1-1) of the battery, advantageously dry charged, by its electrolyte and a stage of measurement (E1-2), associated with the impregnation, of a rise in the temperature of the battery or of a value representative of the density of the electrolyte, so as to determine the value representative of the amount of lead oxide present before the impregnation. In fact, the term “associated with the impregnation” is understood to mean that the value measured, of rise in temperature or of value representative of the density, is a function of the chemical reaction associated with the impregnation, that is to say that it results from the impregnation stage. Typically, the measurements of the rise in temperature or of the value representative of the density will be determined during the impregnation stage.

The term “value representative of the density” is understood to mean, in the continuation of the present description, either an electrolyte density value which is directly measured, in particular after a period of time subsequent to the beginning of the impregnation stage, or a decrease in the density of the electrolyte resulting from the impregnation stage.

The measurement of the rise in temperature is advantageous in the context where the reaction of equation (1) is exothermic and thus easily measurable, whereas the value representative of the density (brought about by the reaction during the impregnation) requires withdrawing the electrolyte in order to determine the density thereof. Although the method employing the study of the density is more precise than the method employing the rise in temperature, since an extensive physical quantity which is exclusively characteristic of the electrolyte is measured (the other constituents of the battery have an influence on the rise in temperature), it will not be able to be carried out continuously as it advantageously requires several consecutive samplings of electrolyte immediately after the filling and during the impregnation; this measurement of the value representative of the density is thus more difficult to automate. In fact, it is preferable to carry out several measurements continuously after having added the electrolyte, so as to be certain that the density is no longer changing. In addition, the value representative of the density can depend on the temperature of the electrolyte; a person skilled in the art knows to apply the appropriate corrective.

Generally, the rise in temperature or the decrease in density is representative of the maximum variation in temperature or in density due to the impregnation, that is to say when the reaction associated with equation (1) is carried out. In fact, knowing the initial temperature of the battery before impregnation or the initial density of the electrolyte before impregnation, the aim is to measure here the greatest value for temperature or the smallest value for density, generally representative of the corresponding value obtained when the reaction of equation (1) is complete. The maximum variation is then obtained by comparison of the initial value for temperature or, if appropriate, the initial value for density with the maximum value for temperature or, if appropriate, the minimum value for density.

As mentioned above, during the impregnation stage, the lead oxide is preferably converted in full into PbSO₄. Thus, preferably, before initiating the phase of charging the battery, it will be necessary to wait for the reaction associated with equation (1) to be complete. For example, this reaction will be complete when a maximum temperature is reached and when the temperature tends to decrease or when the density of the electrolyte will become stabilised after an impregnation time of at least two hours, in order to make sure that the electrolyte has indeed penetrated into the porosities of the active material of the battery.

According to a specific implementation of the process, the value representative of the amount of lead oxide corresponds to an initial rate of lead oxide present before impregnation. Advantageously, the charging time t_{ch} in hours is given by the following equation

$${t}_{ch} = \frac{\% PbO \times 2 \times F \times {w}_{T}}{I \times M ( PbO ) \times 3600} , \qquad ( 3 )$$

with F the Faraday constant, w_{T} the total weight of negative active material of the battery, in particular in grams, M(PbO) the molar mass of the lead oxide, in particular in grams per mole, I the charging current, in particular in amperes, and % PbO the rate of lead oxide, in particular as a percentage.

The total weight of negative active material w_{T} corresponds to the material pasted onto plates of the battery forming the anode. In fact, the negative plates of a battery comprise a metal lead grid onto which the active material is pasted (at the end of the manufacture, 92 to 94% of lead is present, plus additives varying according to the manufacturers). The lead grid and a portion of the paste do not participate in the electrochemical charging or discharging reactions but participate in the satisfactory electrical conduction of the assembly. The associated weight w_{T} value can be known for a type of battery by taking a fresh battery of the same type and by then removing the active material pasted onto all the negative plates of the battery, so as to weigh it. Of course, this weight value information may be communicated, if appropriate, by the manufacturers.

In fact, in the context of the validation of the charging process using the PbO rate to determine the charging time of the battery, chemical tests have been carried out which make it possible to theoretically determine the amount of lead oxide on the negative plates from samples of pasted material withdrawn from a negative plate of other batteries. Reference is made to “other batteries” because the samples taken in order to carry out the chemical analyses are destructive for these batteries; consequently, the latter can subsequently no longer be impregnated. The results of these tests have acted as reference for the comparisons with the determination of the amount of lead oxide deduced by constant current coulometry.

As the chemical tests have been carried out on samples and not on the whole of the weight w_{T}, the rate of lead oxide was selected as criterion for determining the charging time. The results of the constant current coulometry have thus, for reasons of comparison, also been expressed as rate of lead oxide. However, as the coulometry uses the whole of the negative active material of the battery, it is necessary, in the example, to know the total weight of negative active material w_{T} pasted onto the negative plates of a fresh battery.

Thus, it is understood that the use of the rate of lead oxide is only a specific embodiment which makes it possible to determine an optimum charging time of a battery. Thus, it is also possible to consider that it is possible to evaluate this charging time by linking a rise in temperature to a weight (instead of the rate) of lead oxide determined by constant current coulometry, this being the case without having to know the total weight of active material. This would make it possible to determine the optimised charging time by the following formula:

$${t}_{ch} = \frac{{w}_{PbO} \times 2 \times F}{I \times M ( PbO ) \times 3600} ,$$

where w_{PbO} denotes the weight of PbO in grams, evaluated using a nomogram associating the value of rise in temperature or the value representative of the density with a weight of PbO. Nevertheless, by using the weight, diagnostic information on the extent of the oxidation is lost; for example, for a value of 3 grams of PbO, it is difficult to know if the oxidation of the battery is truly significant. Thus, the rate of lead oxide is preferred as it makes it possible, for example by simple reading by an operator, to know if the battery does or does not exhibit significant oxidation.

Generally applicable to everything which has been said above, the determination of the value representative of amount of lead oxide can be carried out starting from a nomogram giving the said value representative of the amount of lead oxide as a function of the rise in the temperature of the battery or of the value representative of the density of the electrolyte.

According to a specific embodiment, the charging time t_{ch} for the battery can be determined from a nomogram giving the said time as a function of the rise in the temperature or of the value representative of the density, the said rise in temperature or the value representative of the density being correlated with the value representative of amount of lead oxide. In fact, the nomogram can correspond to a table giving different values of rise in temperature or values representative of the density, each associated with a value for charging time.

Generally, the charging of the battery is carried out with a constant current. Thus, preferably, the nomogram takes account of this current value. It will thus be possible, as a function of the current, to have several possible values for charging time.

According to an alternative form, the nomogram corresponds to a simple multiplying coefficient which it is sufficient to multiply by the value of rise in temperature in order to obtain the charging time. The nomogram can also correspond to an equation, the result of which, by injecting the measured value of rise in temperature or the value representative of the density, gives the value representative of the amount of lead oxide present before impregnation, that is to say, if appropriate, the charging time, or the rate of PbO.

Generally applicable to all the implementations of the charging process, during the initialisation phase E1, the impregnation is carried out by filling, in one go, the battery with its electrolyte. This makes it possible, inter alia, to obtain a maximum rise in temperature.

It results from that which was described above that it is preferable to suitably generate a nomogram to associate with the charging process.

Thus, the invention also relates to a process for the generation of a nomogram intended to be used in the charging process. Such a process comprises the generation of the nomogram from at least one measurement of a physical parameter of an at least partially oxidized lead battery and the correlation of this measurement with a value representative of an amount of lead oxide in the battery. This measured physical parameter can be the rise in temperature of the battery or the value representative of the density of the electrolyte added during the impregnation.

The process for generating the nomogram can be carried out starting from at least one standard battery, in particular stored dry charged, and representative of the type of battery which will later be used in the charging process. The term “type of battery” is understood to mean batteries having the same physical characteristics.

Advantageously, in the context of a nomogram employing the rise in temperature, just one standard battery may be sufficient. In the context of a nomogram employing the value representative of the density, use will advantageously be made of two standard batteries.

Subsequently, the initial tests which made it possible to show the possibility of drawing up the nomogram were carried out on a batch of nine dry charged standard batteries of the same type and of Exide 12 OPzS 1200LA brand comprising three new nonstored batteries (Ref-01 to Ref-03), that is to say not oxidized to any great extent, and six batteries which had been stored outside the time limits and under uncontrolled storage conditions (A-05 to A-07 and B-09 to B-11), that is to say potentially strongly oxidized.

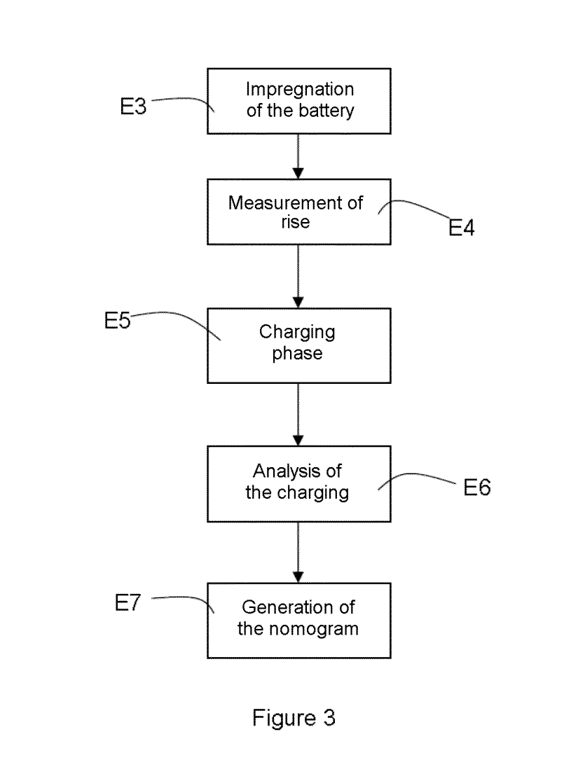

Advantageously, the process for the generation of the nomogram comprises different test stages, as illustrated in FIG. 3.

In a first step, an impregnation E3 of the battery is carried out by filling it with electrolyte so that the lead oxide is converted in full into PbSO₄. This impregnation makes it possible to carry out the reaction of equation (1). E4, a rise in temperature of the battery or a value representative of the density of the electrolyte, associated with the impregnation, is then measured.

In a second step, a phase E5 of charging the battery is carried out. This charging phase is preferably carried out only when the reaction associated with equation (1) is complete. This charging phase is, in addition, analysed E6.

Finally, the nomogram is generated E7 from the analysis of the charging phase, and the rise in temperature of the battery, or the value representative of the density of the electrolyte.

According to a specific implementation, the charging phase E5 is carried out with a constant current with measurement of the change in the voltage at the terminals of the battery. The stage E6 of analysis of the charging phase makes it possible, on the one hand, to determine, from the change in the voltage during the charging phase, the amount of PbSO₄ converted into lead (see above for the method) and, on the other hand, to determine, from a chemical reaction equation (in particular equation (1)) and from the amount of PbSO₄ converted into lead, the initial amount of lead oxide before impregnation, so that the generation of the nomogram takes into account the initial amount of lead oxide before impregnation.

In fact, according to this implementation, the initial amount of lead oxide before impregnation can be determined as described above, in particular by using FIG. 2 and equations (1) and (2).

This amount of lead oxide can advantageously be a rate of lead oxide.

Consequently, the nomogram can be generated so as to give the value representative of the amount of lead oxide as a function of the measured rise in temperature or of the value representative of the density measured.

Table I below makes it possible to correlate a rise in temperature ΔT with a rate of lead oxide for the various standard batteries mentioned above after the test stages have been carried out for each standard battery.

TABLE I

| | Ref- | Ref- | Ref- | | | | | | |
|---|---|---|---|---|---|---|---|---|---|
| Factor | 01 | 02 | 03 | A-05 | A-06 | A-07 | B-09 | B-10 | B-11 |
| ΔT | +1 | +2 | +2 | +15 | +15 | +12 | +26 | +14 | +14 |
| (° C.) | | | | | | | | | |
| % PbO | 4.1 | 6.2 | 5.7 | 24.9 | 24.4 | 19.7 | >30 | 22.6 | 26.7 |

This table can subsequently be used for one and the same type of dry charged battery which it is desired to initialise by filling it with electrolyte. Typically, during the charging process, knowing the rise in temperature, it is possible to determine the rate of lead oxide from Table I and then to inject it into equation (3) in order to determine the charging time of the battery. In other words, the nomogram can be generated so as to give a rate of lead oxide as a function of a measured rise in temperature or of the value representative of the density measured.

According to an alternative form, the nomogram is generated so as to give a charging time as a function of the measured rise in temperature or of the value representative of the density measured. This alternative form can be implemented by combining Table I with Table II below, which gives the charging time in hours as a function of the rate of lead oxide.

TABLE II

| | Ref- | Ref- | Ref- | | | | | | |
|---|---|---|---|---|---|---|---|---|---|
| Factor | 01 | 02 | 03 | A-05 | A-06 | A-07 | B-09 | B-10 | B-11 |
| % PbO | 4.1 | 6.2 | 5.7 | 24.9 | 24.4 | 19.7 | >30 | 22.6 | 26.7 |
| t in h | 1.6 | 2.4 | 2.2 | 9.6 | 9.4 | 7.6 | >18 | 8.7 | 10.3 |

This Table II can be obtained by using Table I and starting from equation (3) during the process for generating the nomogram. This will have the advantage of rendering the charging process simpler to carry out since all the calculations will have been carried out during the generation of the nomogram and since a simple reading of the nomogram can be sufficient during when the charging process is carried out to determine the charging time.

Generally, the nomogram is completed by repeating of the test stages at different oxidations so as to generate a plurality of data. These test stages can be carried out on different standard batteries of the same type as produced above for the standard batteries referenced Ref-01 to 03, A-06 to 07 and B-09 to 11.

Although the tables have been generated by taking into account the degree of rise in temperature, the same principle can be applied in generating tables taking into account the value representative of the density.

According to a preferred implementation, the test stages are repeated, in particular on different dry charged batteries of the same type, so as to obtain a plurality of pairs including the value representative of the amount of lead oxide and a value for measured rise in temperature or a value representative of the density measured. From the pairs, a stage of determination of an equation, in particular a straight-line equation, by linear regression can be carried out so that the nomogram comprises only a single equation, making it possible, during the charging process, to determine the value representative of the amount of lead oxide by simply injecting, into the said equation, the measured value for rise in temperature of the battery or the value representative of the density measured for the electrolyte.

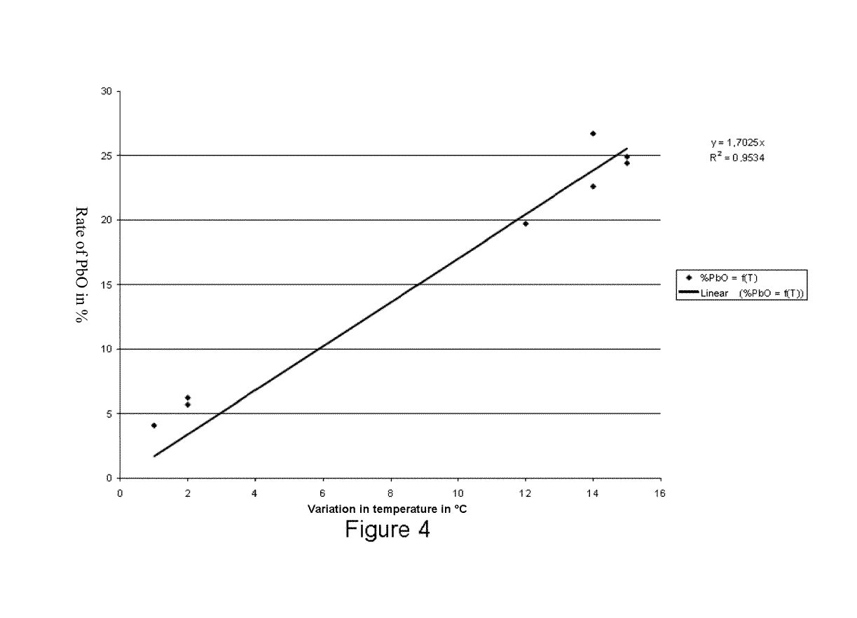

This preferred implementation can be visualised in FIG. 4, where the pairs of rate of PbO as % as a function of the rise in temperature in ° C. have been placed according to points and combined with a straight line determined by linear regression starting from the said points. Thus, starting from FIG. 4, the rate of PbO is equal to 1.7 times the rise in temperature as, in this specific case, the straight-line equation is y=1.7025x. R² corresponds to the correlation coefficient of the linear regression; the closer it is to 1 (it is always less than or equal to 1), the more relevant the linear regression modelling the data.

In FIG. 4, the equation of the straight line is an equation passing through the origin. It was mentioned above that a single battery might be sufficient. This is due to the fact that this straight line passes through the origin. Specifically, in the context of a simplification of the characterization of the batteries, by testing a single battery and by generating a graph of the type of FIG. 4 with a straight line passing through the point resulting from the single test and through the origin of the graph, it is possible to determine the equation of the straight line. Although this makes it possible to facilitate the calculations, this implementation is not advantageous as it does not make it possible to smooth out the possible defects of a battery.

By using this relationship of 1.7, it is possible to estimate the rate of PbO of the element B-09 (ΔT=+26° C.) at a value of approximately 44%. This means that, with a constant current charge of 70 A, 18 hours are sufficient to achieve the complete charging of this battery (application of equation 3 in the case where w_{T} is known). It is preferable to provide a slight additional charge (a further 1 to 2 hours) in order to delaminate the electrolyte by degassing. This is advantageous as, at 70 A, the recommendations of the suppliers, which include an excessively large safety margin, are instead of the order of 48 h.

As regards a straight line passing through the origin, it is possible, in the context of the rise in temperature, for the nomogram to correspond to a multiplying coefficient which directly gives the charging time in hours once multiplied by the rise in temperature during the phase of initialisation of the process for charging a battery.

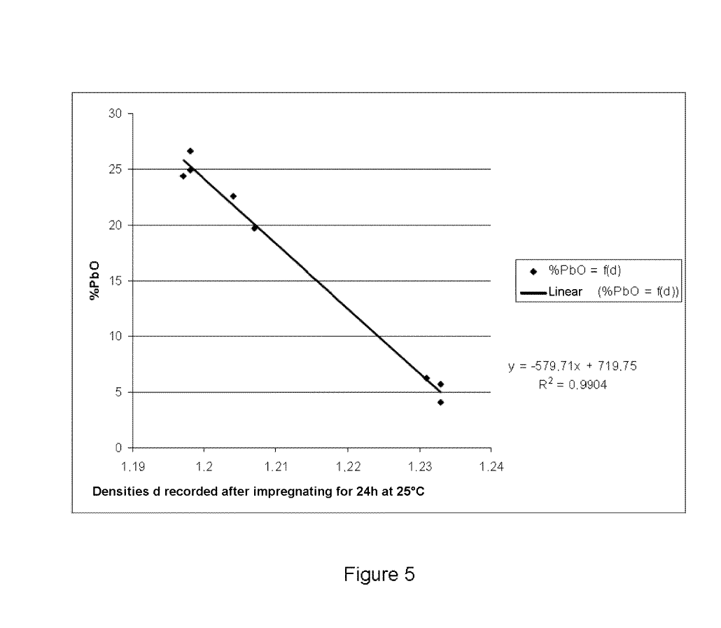

Of course, this linear regression can also be employed for the value representative of density of the electrolyte, as illustrated in FIG. 5, which gives the change in the rate of PbO in % as a function of the density. The density value of a point of the graph corresponds to the density measured after impregnating for 24 h when the temperature of the battery has returned to ambient temperature, i.e. 25° C. in the specific example. The different points of the graph are obtained by testing different batteries of the same type. The lowest density values measured correspond to a mass transfer of the sulphate ions from the electrolyte towards the negative plates, this transfer becoming greater in proportion as the plates are initially oxidized before impregnation. According to the straight line obtained y=−579x+719.75, the rate of PbO exists which is equal to −579.71 times the density, plus 719.75. R² corresponds to the correlation coefficient of the linear regression. It is possible to measure the density sooner, that is to say without waiting 24 hours, but it is necessary to allow at least two hours to pass after having added the electrolyte, in order to make sure the electrolyte has indeed penetrated the whole of the porosity of the active material.

It will have been understood that, in the context of FIG. 5, the straight line does not pass through the origin. It is for this reason that it is advantageous to carry out the tests on at least two batteries so as to generate the straight line, for example solely as a function of these two points, in order to facilitate the generation of the nomogram while avoiding the linear regression originating from several tests. Of course, in this particular case, the slightest error in the measurements will result in a distorted straight line equation being drawn up.

When the value representative of the amount of lead oxide is a rate of lead oxide, the process for the generation of the nomogram can comprise a stage of determination of a total weight of negative active material w_{T} associated with the battery and the deduction of the rate of lead oxide from the total weight of active material w_{T} and the initial amount of lead oxide determined. w_{T} can be determined as described above by deploying a new battery of the same type and by studying it.

It should be noted that, as soon as the total weight of active material w_{T} (which depends on the type of battery) is known, it is possible to use nomograms which depend only on the current used and on the measurement of change in the temperature of the battery or on the density of the electrolyte providing w_{PbO} (the charging time then subsequently being calculated by application of

$${t}_{ch} = \frac{{w}_{PbO} \times 2 \times F}{I \times M ( PbO ) \times 3600} ) .$$

It was specified above that the electrolyte is generally added in one go during the phase of initialisation of the charging process or during the impregnation in the process for the generation of the nomogram. If all of the electrolyte is added all at once and rapidly, the rise in temperature will be large and will momentarily promote the reaction for self-discharge of the battery. This reaction converts a small portion of the lead into lead sulphate and is accompanied by a release of dihydrogen gas. This reaction also takes place at ambient temperature but it is very disadvantaged kinetically (approximately 1 month is necessary for 5% of the active material to undergo this reaction at ambient temperature). The kinetics follow an exponential law as a function of the temperature, which experience a doubling in their rate for an increase of 10° C. in the temperature. During the tests, the temperature could increase by more than 20° C. for approximately fifteen hours, which corresponds to an attack on 0.1% of the negative active material, a value which is thus negligible in the context of the present invention.

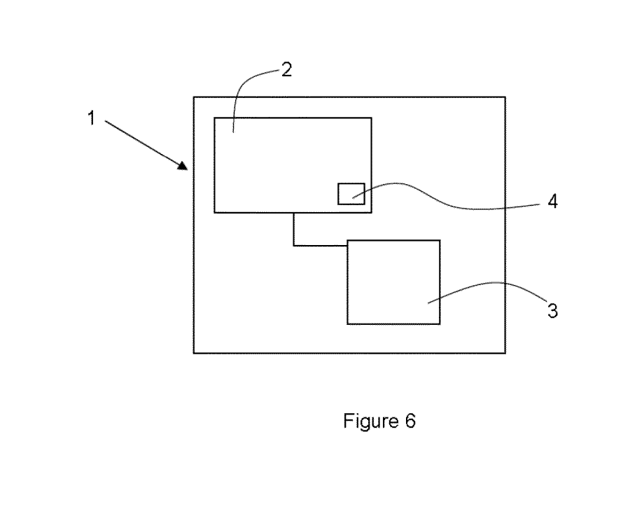

In the context of the implementation of the charging process, a device 1 illustrated in FIG. 6 can comprise a battery 2 and a calculation unit 3 configured in order to carry out the charging process. In addition, in the embodiment where it is desired to measure an increase in temperature, the device can comprise a temperature sensor 4, in particular of thermocouple type, configured in order to measure the rise in the temperature of the battery during the initialisation phase. This sensor will advantageously be installed at a median point of the external side faces of a case perpendicular to the plates. The sensor can also be placed in the electrolyte but would have to withstand sulphuric acid. This temperature sensor can at the same time be associated with a casing comprising an electronic board implemented by the nomogram and including an algorithm for the calculation of the estimated rate of lead. From the charging time deduced (nomogram of Table II type), it is possible to envisage automatically triggering the corresponding charging. The presence of an operator is then necessary only for the pause of the sensor and the filling of the battery. The electronic board can be implemented by multiple nomograms corresponding to different types of batteries envisaged, thus making it possible to easily adapt the device to different batteries.

A data recording medium readable by a computer, on which a computer program is recorded, can comprise computer program code means for implementing the stages and/or phases of the charging process (preferably all the stages and/or phases of the charging process).

A computer program can comprise a computer program code means suitable for carrying out the stages and/or phases of the charging process (preferably all the stages and/or phases of the charging process), when the program is executed by a computer.

Such a charging process is advantageous for activities involving the storage of dry charged lead batteries over a long period of time, which period of time may exceed the recommendations of the suppliers. The method makes it possible to rapidly make a diagnosis with regard to the state of health of the batteries and to optimise their first charging after filling with the electrolyte, so as not to damage them.

During the charging process, if the battery is only slightly oxidized, the aim will not be to calculate a charging time in an optimized manner. Thus, for example, if the rise in temperature during the impregnation is less than 5° C., indeed even less than 3° C., a predetermined charging time will be systematically applied. For example, for a battery of Exide 12 OPzS 1200 brand for charging at 70 A, the charging time will be 8 hours in order to immediately restore the initial nominal capacity of the battery.

In the present description, the term “battery” is understood to mean both an individual battery and a plurality of individual batteries arranged and connected electrically in order to form an array.

1. Process for charging a lead battery, comprising:
determining, during an initialisation phase, a value representative of an amount of lead oxide of the negative active material of the battery, and
charging the battery during a charging phase, the duration of which is determined as a function of the value representative of amount of lead oxide.

2. Process according to claim 1, wherein the initialisation phase comprises a stage of impregnation of the battery by its electrolyte and a stage of measurement, associated with the impregnation, of a rise in the temperature of the battery or of a value representative of the density of the electrolyte, so as to determine the value representative of the amount of lead oxide present before the impregnation.

3. Process according to claim 2, wherein, during the impregnation stage, the lead oxide is converted in full into PbSO₄.

4. Process according to claim 2, wherein the determination of the value representative of amount of lead oxide is carried out starting from a nomogram giving the said value representative of the amount of lead oxide as a function of the rise in the temperature or of the value representative of the density.

5. Process according to claim 2, wherein the value representative of the amount of lead oxide corresponds to an initial rate of lead oxide present before impregnation.

6. Process according to claim 5, wherein the charging time t_{ch} in hours is given by the following equation
$${t}_{ch} = \frac{\% PbO \times 2 \times F \times {w}_{T}}{I \times M ( PbO ) \times 3600} ,$$
with F the Faraday constant, w_{T} the total weight of negative active material of the battery, M(PbO) the molar mass of the lead oxide, I the charging current and % PbO the rate of lead oxide.

7. Process according to claim 2, wherein the charging time is determined from a nomogram giving said charging time as a function of the rise in the temperature or of the value representative of the density, the said rise in the temperature or the value representative of the density being correlated with the value representative of amount of lead oxide.

8. Process according to claim 1, wherein, during the initialisation phase, the impregnation is carried out by filling, in one go, the battery with its electrolyte.

9. Process for the generation of a nomogram intended to be used in the process according to claim 1, which comprises generating the nomogram from at least one measurement of a physical parameter of an at least partially oxidized lead battery and correlating the measurement with a value representative of an amount of lead oxide of the negative active material of the battery.

10. Process according to claim 9, which comprises the following test stages:
Carrying out an impregnation of the battery by filling the battery with electrolyte so that the lead oxide is converted in full into PbSO₄,
Measuring a rise in temperature of the battery or a value representative of the density of the electrolyte, associated with the impregnation,
Carrying out a phase of charging the battery,
Analysing the charging phase,
Generating the nomogram from the analysis of the charging phase, and the rise in temperature of the battery, or the value representative of the density of the electrolyte.

11. Process according to claim 10, wherein the charging phase is carried out with a constant current with measurement of the change in the voltage at the terminals of the battery and wherein the stage of analysis of the charging phase makes it possible (i) to determine, from the change in the voltage during the charging phase, the amount of PbSO₄ converted into lead, and (ii) to determine, from a chemical reaction equation and from the amount of PbSO₄ converted into lead, the initial amount of lead oxide before impregnation, so that the generation of the nomogram takes into account the initial amount of lead oxide before impregnation.

12. Process according to claim 10, wherein the nomogram is generated so as to give the value representative of the amount of lead oxide as a function of the measured rise in temperature or of the value representative of the density measured.

13. Process according to claim 10, wherein the nomogram is generated so as to give a charging time as a function of the measured rise in temperature or of the value representative of the density measured.

14. Process according to claim 12, wherein the nomogram is completed by repeating the test stages at different oxidations so as to generate a plurality of data.

15. Process according to claim 10, wherein the test stages are repeated so as to obtain a plurality of pairs including the value representative of the amount of lead oxide and a value for measured rise in temperature or a value representative of the density measured, and wherein the process comprises, from the pairs, a stage of determination of an equation by linear regression so that the nomogram comprises only a single equation.

16. Process according to claim 1, wherein the nomogram is generated so as to give a charging time as a function of the measured rise in temperature or of the value representative of the density measured, wherein the value representative of the amount of lead oxide is a rate of lead oxide, and wherein the process comprises a stage of determination of a total weight of negative active material w_{T} associated with the battery and the deduction of the rate of lead oxide from the total weight of active material w_{T} and the initial amount of lead oxide determined.

17. Device comprising a battery and a calculation unit configured in order to carry out the process according to claim 1.

18. Device according to claim 17, which comprises a temperature sensor configured in order to measure the rise in the temperature during the initialisation phase.

19. Data recording medium readable by a computer, on which is recorded a computer program comprising computer program code means for implementing the phases and/or stages of a process according to claim 1.

20. Computer program comprising a computer program code means suitable for carrying out the phases and/or stages of a process according to claim 1, when the program is executed by a computer.
